(19) United States
(12) Patent Application Publication
(10) Pub. No.: US 2025/0167036 A1
(43) Pub. Date: May 22, 2025

(54) MULTIZONE COATED VACUUM CHUCK FOR IR MEASUREMENT

(71) Applicant: Applied Materials, Inc., Santa Clara, CA (US)

(72) Inventor: Sanjay BHAT, Singapore (SG)

(21) Appl. No.: 18/516,849

(22) Filed: Nov. 21, 2023

(51) Int. Cl. H01L 21/683; H01L 21/68; H01L 21/687

(52) U.S. Cl. CPC H01L 21/6838; H01L 21/681; H01L 21/68785

(57) ABSTRACT

Embodiments of chuck plates for a substrate support are provided herein. In some embodiments, the chuck plate includes an upper surface defining a support surface for a substrate and having a coating comprising a material with less reflectivity than a base material of the chuck plate, wherein the upper surface includes a plurality of vacuum grooves, wherein the plurality of vacuum grooves are arranged in a plurality of zones that are fluidly independent from each other along the upper surface and fluidly coupled to a common vacuum port disposed at a lower surface of the chuck plate.

### FIELD

Embodiments of the present disclosure generally relate to substrate processing equipment.

### BACKGROUND

Hybrid bonding is a semiconductor process that generally comprises vertically bonding closely spaced copper pads of one or more dies to a wafer via a die-to-wafer (D2W) or wafer-to-wafer (W2W) process to form a bonded wafer, or substrate. Post-bonding analysis may be performed on the substrate via metrology chambers to determine if dies are bonded properly. A typical metrology chamber includes a substrate support configured to hold the substrate and a measurement device such as an IR imaging device disposed above the substrate support for taking measurements or images of the bonding interface between the wafer and the bonded dies. However, the inventors have observed that IR imaging devices often detect unwanted signatures of the substrate support along with the one or more dies and wafer, which contaminates the results.

Vacuum chucks are often used to chuck the substrate thereto during processing, such as post-bond analysis. However, the inventors have observed that the substrate needs to be flat to avoid measurement errors. The substrate having even a slight warpage may lead to leakage and poor suction against an upper surface of the vacuum chuck. Accordingly, the inventors have provided herein embodiments of improved substrate supports.

### SUMMARY

Embodiments of chuck plates for a substrate support are provided herein. In some embodiments, the chuck plate includes an upper surface defining a support surface for a substrate and having a coating comprising a material with less reflectivity than a base material of the chuck plate, wherein the upper surface includes a plurality of vacuum grooves, wherein the plurality of vacuum grooves are arranged in a plurality of zones that are fluidly independent from each other along the upper surface and fluidly coupled to a common vacuum port disposed at a lower surface of the chuck plate.

In some embodiments, a chuck plate for a substrate support includes a body having an upper surface defining a support surface for a substrate and having a coating comprising a material with less reflectivity than a base material of the chuck plate, wherein the upper surface includes a plurality of vacuum grooves, wherein the plurality of vacuum grooves are arranged in a plurality of zones that are fluidly independent from each other along the upper surface; a cover plate coupled to a lower surface of the body to define a plenum therebetween, wherein the cover plate includes a common vacuum port extending through the cover plate to the plenum; and a plurality of vacuum holes extending from the plenum to the plurality of vacuum grooves for each of the plurality of zones.

In some embodiments, a metrology chamber includes an enclosure defining an interior volume therein; a substrate support disposed in the interior volume, wherein the substrate support comprises a chuck plate having: an upper surface defining a support surface for a substrate and having a coating comprising a material with less reflectivity than a base material of the chuck plate, wherein the upper surface includes a plurality of vacuum grooves, wherein the plurality of vacuum grooves are arranged in a plurality of zones that are fluidly independent from each other along the upper surface and fluidly coupled to a common vacuum port disposed at a lower surface of the chuck plate; and an optical inspection system disposed in the interior volume above the chuck plate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a metrology chamber in accordance with at least some embodiments of the present disclosure.

FIG. 2 depicts an isometric top view of a chuck plate in accordance with at least some embodiments of the present disclosure.

FIG. 3 depicts an isometric bottom view of a chuck plate in accordance with at least some embodiments of the present disclosure.

FIG. 4 depicts a cross-sectional side view of a chuck plate in accordance with at least some embodiments of the present disclosure.

FIG. 5 depicts an isometric bottom view of a chuck plate with a cover plate in accordance with at least some embodiments of the present disclosure.

FIG. 6 depicts an isometric top view of a portion of a chuck plate having a calibration plate in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of chuck plates for a substrate support are provided herein. The chuck plates described herein are typically used to provide a support and/or chucking surface of a substrate disposed in a process chamber, for example, a metrology chamber. The metrology chamber may be configured for performing an optical inspection or measurement via an optical imaging system on the substrate disposed therein. The chuck plate advantageously includes a coating on at least an upper surface thereof that is less reflective than a base material of the chuck plate to reduce or prevent reflection of signatures (e.g., gas groove patterns) of the chuck plate during optical inspection. For example, in a metrology chamber that performs an optical measurement, for example an IR measurement of a substrate comprising one or more dies bonded to a wafer to detect defects at a bond interface between the one or more dies and the wafer, the chuck plate having the coating reduces or prevents unwanted signatures of the chuck plate from being visible and contaminating an IR image of the substrate along the bond interface. The reduction or prevention of such signatures advantageously reduces post image processing time and the propensity of erroneous results.

The chuck plates provided herein may also advantageously include multizone vacuum chucking capabilities for effectively chucking warped substrates. Good measurements in the metrology chamber require a high level of flatness. Warped substrates may prevent the optical imaging system from obtaining accurate measurements. Thus, the multizone vacuum chucking capability of the chuck plate advantageously helps pull, or chuck, the substrate in each zone for a better suction between the substrate and the chuck plate. A warped substrate disposed on a single zone vacuum chuck may leak at the warped regions of the substrate, thereby preventing good suction of the substrate across an entire surface of the substrate.

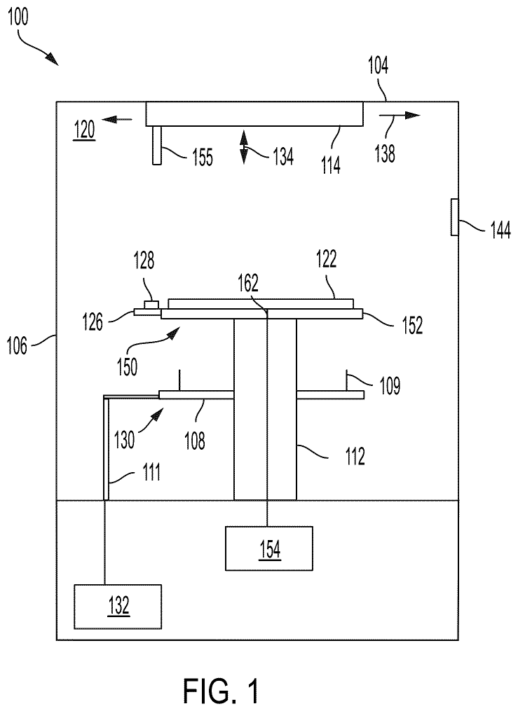

FIG. 1 depicts a schematic side view of a process chamber 100 in accordance with at least some embodiments of the present disclosure. In some embodiments, the process chamber 100 is a metrology chamber. However, other types of processing chambers configured for different processes can also be modified for use with embodiments of the substrate supports described herein. The process chamber 100 generally includes an enclosure 106 covered by a top plate 104 which defines an interior volume 120 of the process chamber 100. The enclosure 106 and the top plate 104 may be made of metal, such as aluminum.

A substrate support 124 is disposed within the interior volume 120 to support and retain a substrate 122, such as a semiconductor wafer, for example, or other such substrate. The substrate support 124 may generally comprise a pedestal 150 and a stage 112 for supporting the pedestal 150. The pedestal 150 generally comprises a chuck plate 152 disposed on a stage 112. The stage 112 may generally comprise one or more plates that may be coupled to one or more actuators or motors (not shown for simplicity) to rotate the chuck plate 152 or provide lateral or side-to-side movement of the chuck plate 152 in the interior volume 120. The stage 112 may also be configured to provide up and down movement of the chuck plate 152 in the interior volume 120. The chuck plate 152 may be coupled to a vacuum system 154 configured to vacuum chuck the substrate 122 to the chuck plate 152 via a plurality of vacuum holes 162. The vacuum system 154 generally includes a vacuum pump and one or more valves. The stage 112 may include features such as slots or openings for lines or conduits, for example, backside gases, vacuum suction, power, or the like, to the pedestal 150. A vacuum line from the vacuum system 154 to the chuck plate 152 may extend through the stage 112 or around the stage 112.

The process chamber 100 includes a slit valve 144 to facilitate transferring the substrate 122 into and out of the interior volume 120. In some embodiments, a transfer robot (not shown) is configured to transfer the substrate 122. A substrate lift 130 can include lift pins 109 mounted on a platform 108 connected to a shaft 111 which is coupled to a lift mechanism 132 for raising and lowering the substrate lift 130 so that the substrate 122 may be placed on or removed from the chuck plate 152. The chuck plate 152 may include through holes or slots to receive the lift pins 109.

An optical inspection system 114 is disposed in the interior volume 120 above the chuck plate 152. The optical inspection system 114 may generally include one or more cameras 155 and associated components for processing data captured by the one or more cameras 155. In some embodiments, the optical inspection system 114 comprises an infrared camera. In some embodiments, the optical inspection system 114 comprises an infrared camera and a visible light camera. For example, the infrared camera may check for bonding quality of dies on the substrate while the visible light camera can check for wafer and die alignment. The optical inspection system 114 may be configured for movement in a lateral direction 138 in order to scan or image the entire surface of the substrate 122. The optical inspection system 114 may be configured for movement in a vertical direction 134. For example, the optical inspection system 114 may include the one or more cameras 155 coupled to corresponding ones of one or more arms that are configured to move in at least one of the lateral direction 132 or vertical direction 134.

In some embodiments, the chuck plate 152 includes one or more calibration plates 126 coupled to a body of the chuck plate 152. In some embodiments, the one or more calibration plates 126 include three calibration plates out of which one calibration plate can be used based on the configured or application of the process chamber 100. Each of the one or more calibration plates 126 are configured to support a reference semiconductor die 128. In some embodiments, the reference semiconductor die 128 comprises one or more dies bonded to a wafer with no defects. The reference semiconductor die 128 is generally kept at a same height as the substrate 122 so that the optical inspection system 114 can capture the images, or other measurements, of both the reference semiconductor die 128 and the substrate 122 so that the bonds of the substrate 122 can be compared to the reference semiconductor die 128 for defects. The reference semiconductor die 128 can be used to set the parameters of the optical inspection system 114, such as position of the optics, contrast and brightness of the image, and the like. In some embodiments, the one or more calibration plates 126 comprise three plates.

The chuck plate 152 advantageously includes a coating comprising a material with less reflectivity than a base material of the chuck plate 152. In some embodiments, the base material is aluminum or other suitable metal. In some embodiments, the coating comprises an inorganic salt. In some embodiments, the inorganic salt comprises nickel, such as nickel sulfate or nickel phosphate. In some embodiments, the coating is an anodized coating. In some embodiments, the coating has a thickness of about 10 to about 60 microns.

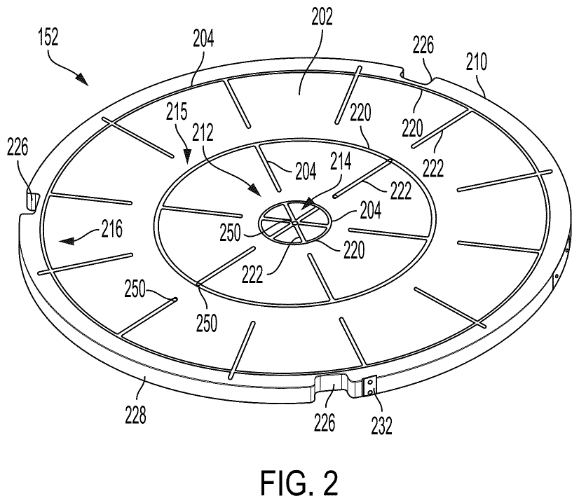

FIG. 2 depicts an isometric top view of a chuck plate 152 in accordance with at least some embodiments of the present disclosure. The chuck plate 152 includes a body 210 having an upper surface 202 defining a support surface for the substrate 122. The support surface may include a plurality of vacuum grooves 204 that provide pathways for vacuum suction provided by, for example, the vacuum system 154 to sufficiently and/or uniformly chuck the substrate 122 to the upper surface 202 when disposed thereon. The plurality of vacuum grooves 204 may be arranged in any suitable pattern. In some embodiments, the plurality of vacuum grooves 204 are arranged in a plurality of zones that are fluidly independent from each other along the upper surface 202. The multiple zones advantageously allows for certain zones of the substrate 122 to be sufficiently chucked to the chuck plate 152 even if other zones have a suction leakage.

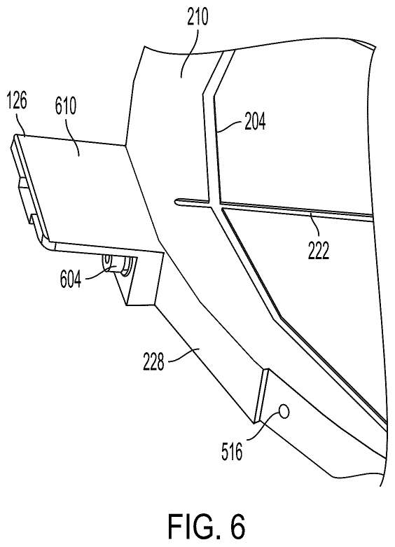

As depicted in FIG. 2, in some embodiments, the plurality of zones comprises three zones that are arranged concentrically. In some embodiments, the plurality of vacuum grooves 204 associated with each of the three zones comprise an annular groove 220 and a plurality of radial grooves 222 extending in a radial direction from the annular groove 220. The annular groove 220 may be circular as depicted in FIG. 2 or comprise a plurality of angular segments that form a closed polygonal shape as depicted in FIG. 6. In some embodiments, a radially innermost zone 212 of the plurality of zones includes an annular groove 220 and a plurality of radial grooves 222 extending radially inward from the annular groove 220 to a common center 214. In some embodiments, a radially outermost zone 216 of the plurality of zones includes an annular groove 220 and one or more radial grooves of the plurality of radial grooves 222 that extend radially inward and outward of the annular groove 220.

The chuck plate 152 includes a plurality of vacuum holes 250 extending from a lower surface of the chuck plate 152 to corresponding ones of the plurality of zones of the plurality of vacuum grooves 204. The plurality of vacuum holes 250 may be the plurality of vacuum holes 162 discussed with respect to FIG. 1. In some embodiments, at least one of the plurality of vacuum holes 250 is disposed along the common center 214. In some embodiments, the plurality of vacuum holes 250 may be fluidly coupled to a common vacuum port (see FIG. 5) that extends from the lower surface of the chuck plate 152 to a plenum (discussed in more detail below) disposed in the chuck plate 152. In some embodiments, the plurality of vacuum holes 250 extend from the plenum to the plurality of vacuum grooves 204 for each of the plurality of zones. In some embodiments, the plurality of vacuum holes 250 extend substantially vertically from the plenum to the plurality of vacuum grooves 204 for each of the plurality of zones.

In use, if the substrate 122 disposed on the chuck plate 152 is warped upward or downward, for example, by about up to 2 mm at an outer edge region of the substrate 122, the substrate 122 may first be vacuum chucked to the radially innermost zone 212 due to the relative flatness of the substrate 122 in that region and smaller surface area of that region. The substrate 122 may then be vacuum chucked to an intermediate zone 215 of the plurality of zones disposed between the radially innermost zone 212 and the radially outermost zone 216. The substrate 122 may then be vacuum chucked to the radially outermost zone 216 of the chuck plate 152. The substrate 122 may be chucked in such a serial manner because the warpage of the substrate 122 may cause suction leakage and delay vacuum chucking of the substrate 122 to the radially outermost zone 216 as compared to the radially innermost zone 212 and the intermediate zone 215.

In some embodiments, the upper surface 202 of the chuck plate 152 has a flatness of about within about 5 to about 20 microns for obtaining accurate substrate measurements. In some embodiments, the chuck plate 152 includes one or more anti-slip guards 232 coupled to an outer sidewall 228 of the body 210 and extending slightly above the upper surface 202 of the body 210. The one or more anti-slip guards 232 are generally configured to prevent the substrate 122 from slipping off the upper surface 202 when disposed thereon. In some embodiments, the chuck plate 152 includes a plurality of slots 226 extending from the outer sidewall 228 to accommodate the lift pins 109. In some embodiments, the chuck plate 152 includes one of the one or more anti-slip guards 232 disposed proximate each of the plurality of slots 226.

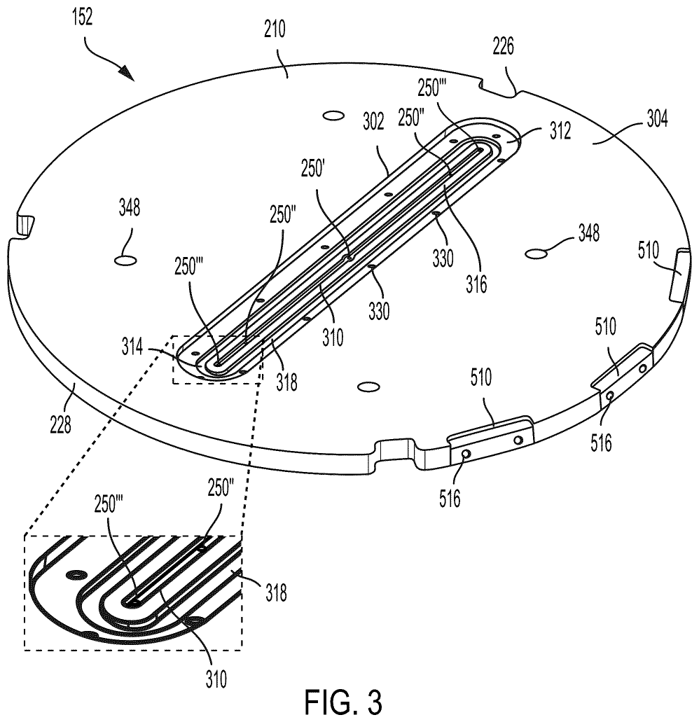

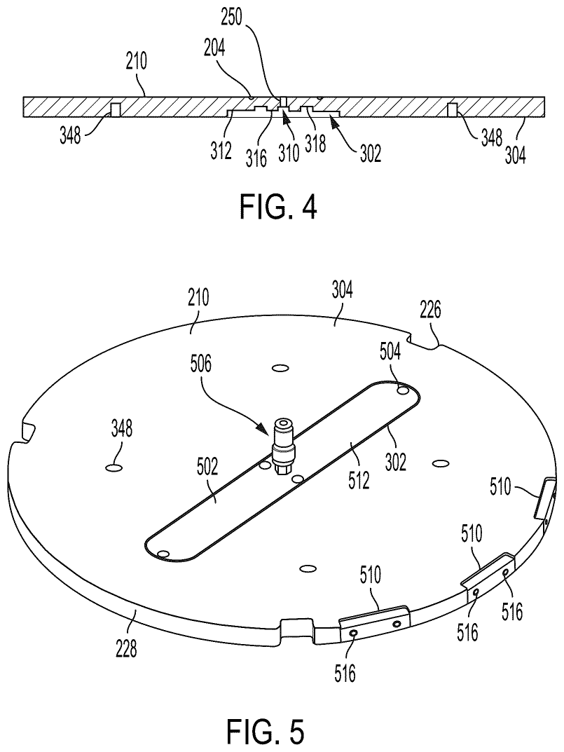

FIG. 3 depicts an isometric bottom view of the chuck plate 152 in accordance with at least some embodiments of the present disclosure. FIG. 4 depicts cross-sectional side view of the chuck plate 152 in accordance with at least some embodiments of the present disclosure. In some embodiments, the chuck plate 152 includes a recess 302 on a lower surface 304 of the body 210. In some embodiments, the recess 302 at least partially defines the plenum 310 that is fluidly coupled to the plurality of vacuum holes 250 that extend to each zone of the plurality of vacuum grooves 204 on the upper surface 202 of the chuck plate 152.

In some embodiments, the recess 302 defines a first floor 312 that is recessed from the lower surface 304 and a second floor 314 that is recessed from the first floor 312. In some embodiments, an enclosed wall 316 extends from the second floor 314 towards the first floor 312 to define the plenum 310 therein. In some embodiments, the second floor 314 is a lowest surface defined by the recess 302. In some embodiments, an o-ring groove 318 is disposed about the enclosed wall 316 to house an o-ring for sealing the plenum 310.

In some embodiments, the chuck plate 152 includes a cover plate 502 (see FIG. 5) coupled to body 210. In some embodiments, the first floor 312 includes fastener openings 330 configured for coupling the body 210 to the cover plate 502 to enclose the enclosed wall 316 and fully define the plenum 310. In some embodiments, the body 210 does not include a recess for the plenum 310 and instead, the cover plate 502 is coupled to the lower surface 304 of the body 210 and includes a recess to define the plenum 310. In some embodiments, the plenum 310 is defined by the recess 302 in the body 210 and a recess in the cover plate 502.

In some embodiments, the plurality of vacuum holes 250 extend from the plenum 310 to the plurality of vacuum grooves 204 for each of the plurality of zones. In some embodiments, a single vacuum hole 250′ of the plurality of vacuum holes 250 extends from the plenum 310 to the radially innermost zone 212. In some embodiments, two vacuum holes 250″ extend from the plenum 310 to the intermediate zone 215. In some embodiments, two vacuum holes 250″ extend from the plenum 310 to the radially outermost zone 216. In some embodiments, the plurality of vacuum holes 250 are linearly aligned along the plenum 310. In some embodiments, the plenum 310 comprises an elongated oval shape to advantageously minimize the volume of the plenum 310 and enhance suction. In some embodiments, the lower surface 304 includes a plurality of mounting holes 348 for coupling the chuck plate 152 to chamber components, such as the stage 112.

FIG. 5 depicts an isometric bottom view of a chuck plate 152 with a cover plate 502 in accordance with at least some embodiments of the present disclosure. The cover plate 502 is coupled to the body 210 to define the plenum 310 therebetween. The cover plate 502 includes a common vacuum port 506 extending through the cover plate 502 to the plenum 310. The cover plate 502 may include a plurality of openings 504 aligned with the plurality of fastener openings 330 to facilitate coupling the cover plate 502 to the body 210. In some embodiments, the cover plate 502 comprises an elongated oval shape. In some embodiments, the cover plate 502 is sized to fit in the recess 302. In some embodiments, a lower surface 512 of the cover plate 502 is coplanar with the lower surface 304 of the body 210.

In some embodiments, the lower surface 512 of the body 210 includes one or more edge recesses 510 adjacent the outer sidewall 228 to accommodate coupling of the one or more calibration plates 126 to the body 210. In some embodiments, the outer sidewall 228 includes a plurality of fastener openings 516 for coupling the one or more calibration plates 126 to the body 210.

FIG. 6 depicts an isometric top view of a portion of a chuck plate 152 having a calibration plate of the one or more calibration plates 126 in accordance with at least some embodiments of the present disclosure. The one or more calibration plates 126 are coupled to the outer sidewall 228 via any suitable manner. For example, one or more fasteners 604 may extend through the one or more calibration plates 126 to the corresponding openings of the plurality of fastener openings 516. The one or more calibration plates 126 may include an upper surface 610 for supporting the reference semiconductor die 128.

While the foregoing is directed to embodiments of the present disclosure, other and further embodiments of the disclosure may be devised without departing from the basic scope thereof.

1. A chuck plate for a substrate support, comprising:
an upper surface defining a support surface for a substrate and having a coating comprising a material with less reflectivity than a base material of the chuck plate, wherein the upper surface includes a plurality of vacuum grooves, wherein the plurality of vacuum grooves are arranged in a plurality of zones that are fluidly independent from each other along the upper surface and fluidly coupled to a common vacuum port disposed at a lower surface of the chuck plate.

2. The chuck plate of claim 1, wherein the common vacuum port extends from the lower surface of the chuck plate to a plenum disposed in the chuck plate, and further comprising a plurality of vacuum holes extending from the plenum to the plurality of vacuum grooves for each of the plurality of zones.

3. The chuck plate of claim 2, wherein the plurality of vacuum holes are linearly aligned along the plenum.

4. The chuck plate of claim 3, wherein the chuck plate comprises a body having the support surface and a cover plate, wherein the cover plate is coupled to a lower surface of the body to define the plenum therebetween.

5. The chuck plate of claim 4, wherein the plenum is at least partially defined by a recess disposed in a lower surface of the body, and wherein the cover plate is sized to fit within the recess.

6. The chuck plate of claim 5, wherein the recess defines a first floor and a second floor that is recessed from the first floor, and wherein an enclosed wall extends from the second floor towards the first floor to define the plenum therein when covered with the cover plate.

7. The chuck plate of claim 1, wherein the coating comprises an inorganic salt.

8. The chuck plate of claim 1, further comprising one or more calibration plates coupled to an outer sidewall of the chuck plate.

9. The chuck plate of claim 1, wherein the plurality of zones consists of three zones, and wherein the plurality of vacuum grooves associated with each of the three zones comprise an annular groove and a plurality of radial grooves extending in a radial direction from the annular groove.

10. A chuck plate for a substrate support, comprising:
a body having an upper surface defining a support surface for a substrate and having a coating comprising a material with less reflectivity than a base material of the chuck plate, wherein the upper surface includes a plurality of vacuum grooves, wherein the plurality of vacuum grooves are arranged in a plurality of zones that are fluidly independent from each other along the upper surface;
a cover plate coupled to a lower surface of the body to define a plenum therebetween, wherein the cover plate includes a common vacuum port extending through the cover plate to the plenum; and
a plurality of vacuum holes extending from the plenum to the plurality of vacuum grooves for each of the plurality of zones.

11. The chuck plate of claim 10, wherein the chuck plate comprises a body having the support surface and a cover plate, wherein the cover plate is coupled to the body to define the plenum therebetween.

12. The chuck plate of claim 10, wherein the body includes a recess on a lower surface thereof, wherein the recess defines an enclosed wall extending from a lowest surface of the recess, wherein the enclosed wall defines the plenum with the cover plate, and wherein an o-ring groove is disposed about the enclosed wall.

13. The chuck plate of claim 10, further comprising one or more anti-slip guards coupled to an outer sidewall of the body and extending above the upper surface of the body and configured to prevent the substrate from slipping off the upper surface.

14. The chuck plate of claim 10, wherein the coating is an anodized coating comprising an inorganic salt comprising nickel.

15. The chuck plate of claim 10, wherein the upper surface of the chuck plate has a flatness of about within about 5 to about 20 microns.

16. A metrology chamber, comprising:
an enclosure defining an interior volume therein;
a substrate support disposed in the interior volume, wherein the substrate support comprises a chuck plate having:
an upper surface defining a support surface for a substrate and having a coating comprising a material with less reflectivity than a base material of the chuck plate, wherein the upper surface includes a plurality of vacuum grooves, wherein the plurality of vacuum grooves are arranged in a plurality of zones that are fluidly independent from each other along the upper surface and fluidly coupled to a common vacuum port disposed at a lower surface of the chuck plate; and
an optical inspection system disposed in the interior volume above the chuck plate.

17. The metrology chamber of claim 16, wherein the optical inspection system comprises an infrared camera.

18. The metrology chamber of claim 16, wherein the plurality of zones comprises three zones that are arranged concentrically, and wherein the chuck plate includes a body and a cover plate coupled to the body to define a plenum therebetween, wherein the plenum comprises an elongated oval shape.

19. The metrology chamber of claim 16, wherein the coating comprises an inorganic salt, wherein the coating has a thickness of about 10 to about 60 microns.

20. The metrology chamber of claim 16, further comprising one or more calibration plates coupled to the chuck plate, wherein the one or more calibration plates are configured to support a reference semiconductor die.
